(19) United States
(12) Patent Application Publication
(10) Pub. No.: US 2006/0051611 A1
(43) Pub. Date: Mar. 9, 2006

(54) Electroluminescent device

(75) Inventors: Klemens Brunner, Eindhoven (NL); Albert Van Dijken, Eindhoven (NL); Herbert Friedrich Boerner, Aachen (DE); Bea Maria Wilhelmina Langeveld, Milsbeek (NL); Nicole Maria Matthias Kiggen, Leveroy (NL); Jolanda Johnna Anna Maria Bastiaansen, Helmond (NL); Margaetha Maria De Kok-Van Breemen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/538,099

(22) PCT Filed: Dec. 5, 2003
(86) PCT No.: PCT/IB03/05782

§ 371 Date: Jun. 8, 2005

(30) Foreign Application Priority Data
Dec. 13, 2002 (EP) 0210754.5
Feb. 12, 2003 (NL) 1022660
Jul. 23, 2003 (EP) 03102262.7

(51) Int. Cl. H05B 33/14

(52) U.S. Cl. 428/690; 428/917; 313/504; 257/102; 257/103; 257/E51.028

(57) ABSTRACT

An electroluminescent device comprises a combination of a charge-transporting conjugated donor compound and a [symbol] acceptor compound, the charge-transporting conjugated donor compound including a conjugated unit comprising a multivalent radical sub-unit having a first and a second unsaturated radical site and a shortest chain of unsaturated atoms connecting the first and the second radical site. The number of unsaturated atoms the shortest chain consists of is an odd integer, preferably 1. Such odd-integer sub-units provide the donor compound with lowest-energy triplet levels which are relatively high in energy which in turn enable the EL device, when the donor compound is combined with a suitable acceptor compound, to emit light with high efficiency. For example, highly efficient green light-emitting electroluminescent devices are obtained in this manner.

The invention relates to an electroluminescent device comprising a combination of a charge-transporting conjugated donor compound and a phosphorescent acceptor compound.

The invention further relates to the use of a charge-transporting conjugated donor compound in such a combination.

An electroluminescent (EL) device is a device which emits light when a suitable voltage is impressed on its electrodes. If the electroluminescent device has an organic material facilitating charge transport and/or light emission it is generally referred to as an organic electroluminescent device. Organic electroluminescent devices can be made, by suitable choice of emissive material, to produce any color at low voltages. Further they are emissive, thin, light weight, flexible and/or of large area rendering such devices suitable for display, signage and lighting applications. An organic electroluminescent device may comprise organic compounds of relatively low molecular weight, also referred hereinafter as small molecule electroluminescent devices, or compounds of high molecular weight, hereinafter also referred to as polymer electroluminescent devices.

It is generally held that in organic electroluminescent devices light emission proceeds by relaxation of excited states, in this context generally referred to as excitons, formed in the emissive material. The excitons are formed by recombination of holes and electrons injected into the EL device by means of electrodes.

In order to achieve light emission upon application of a bias, at least charge transport of holes and electrons, formation of excitons and decay of excitons to the ground state by emission of photons is required. Electroluminescent devices wherein such charge transport and light emission takes place in different species are known as such. See e.g. WO 01/41512. In such combinations a charge-transporting donor compound, in the art also referred to as a host compound, facilitates charge transport and a phosphorescent acceptor compound, in the art also referred to as a guest compound, facilitates light emission. EL devices comprising such combinations have attracted attention in the art because of their alleged ability to harvest triplet excitons which in turn holds the promise of achieving high efficiencies. Accordingly, there is a need for providing EL devices having combinations of donor and acceptor compounds which, by selecting the emission level of the acceptor compound, can be made to emit red, yellow or orange light respectively, but also green light or light of higher frequency, such as blue, with high efficiency.

It is an object of the invention, inter alia, to, at least partially, satisfy that need, that is to provide electroluminescent devices comprising a combination of a charge-transporting conjugated donor compound and a phosphorescent acceptor compound which, by selecting the emission level of the acceptor compound, can be made to emit not only red, yellow or orange light with high efficiency, but also green light or may be light of even higher frequency, such as blue, with high efficiency.

These and others objects are achieved by an electroluminescent device comprising a combination of a charge-transporting conjugated donor polymer and a phosphorescent acceptor compound dispersed in the donor polymer, the charge-transporting conjugated donor polymer having a conjugated chain including one or more odd-integer conjugated multivalent radical sub-units, each odd-integer conjugated multivalent radical sub-unit having a first and a second unsaturated radical site connecting the odd-integer conjugated multivalent radical sub-unit to a respective first and second adjacent conjugated sub-unit of the conjugated chain and a shortest uninterrupted path of unsaturated atoms connecting the first and the second radical site, the number of unsaturated atoms of the shortest path being an odd integer.

Hereinafter, an odd-integer conjugated multivalent radical sub-unit having a first and a second unsaturated radical site connecting the odd-integer conjugated multivalent radical sub-unit to a respective first and second adjacent conjugated sub-unit of the conjugated unit, the odd-integer conjugated multivalent radical sub-unit having a shortest uninterrupted path of unsaturated atoms connecting the first and the second radical site, the number of unsaturated atoms of the shortest uninterrupted path being an odd integer, is referred to as an odd-integer sub-unit for short. The same applies mutatis mutandis to an even-integer sub-unit.

Like any molecular compound, the charge-transporting conjugated donor compound has excited states (excitons) which can be of the triplet or the singlet variety. More particular, there is a lowest-energy singlet and a lowest-energy triplet excited state. Disordered condensed molecular matter such as polymers has a plurality of such lowest states having a certain distribution of energies, the distribution also referred to as density of states. In general, it is well known that if the size of a conjugated system is increased, the energy of the lowest-energy excited state, both triplet and singlet, is lowered.

The inventors have surprisingly found that splicing one or more odd-integer sub-units into a conjugated chain raises the lowest-energy triplet state(s) of such a conjugated chain. Even more surprisingly, the lowest-singlet state does not rise to the same extent thus reducing the singlet-triplet level separation to values of 0.5 eV or less.

Raising the energy of the triplet level of a donor compound extends the range of colors for which such donor compound may be suitably used to obtain highly efficient EL devices. Specifically, the inventors believe that a high efficiency is attainable if the energy of the lowest triplet level of the donor compound is about equal to or higher than the energy of the level of the acceptor compound from which light emission takes place. If such is the case, triplet excitons formed on the donor compound may be effectively transferred to the acceptor compound making them available for efficient light emission and, perhaps more importantly, excitons transferred to or formed on the acceptor compound cannot be transferred back to the donor compound. Enabling transfer from donor to acceptor and disabling back-transfer from acceptor to donor leads to improved efficiency because in general quantum yield of emission from a donor triplet level is very low, much lower than quantum yield of light emission from the acceptor, because such a transition is forbidden. Quantum yield of radiation-less decay from the donor triplet level on the other hand is generally quite high.

Preferably, to obtain highly efficient EL devices, the energy of the lowest-energy triplet of the conjugated chain of the donor compound is higher than the energy of the level of the phosphorescent acceptor compound from which light-emission takes place. The energy of a donor triplet and an acceptor emission level can be routinely determined by recording the phosphorescence emission spectrum of the donor and acceptor compound respectively. If the lowest-energy band of the spectrum shows vibronic progression in the form of a plurality of distinct sub-peaks or is a band with a single maximum and one or more distinct shoulders, the energy is equated to the highest-energy sub-peak or shoulder. In case of an emission band which does not have such features, the peak maximum is considered to be the energy of the triplet level or the emission level.

In the context of the invention, the term “phosphorescent” broadly refers to light emission from a state having a lifetime which is substantially longer than the lifetime of a fluorescent state, the lifetime of the latter being typically about 50 ns or less. More in particular, the term “phosphorescent acceptor compound” refers to a compound having a phosphorescent state from which light emission is more efficient than from the lowest phosphorescent state of the donor compound. The terms “lowest phosphorescent state of the donor compound” and “lowest triplet state of the donor compound” may be used interchangeably.

On an absolute scale, obviously depending on the specific conjugated chain of the donor compound, splicing one or more odd-integer sub-units into a conjugated chain allows triplet levels to be obtained which have an energy which is at least about the same as or larger than the energy of a photon of green light, green light having a wavelength of about 500 nm to about 550 nm. The charge-transporting conjugated donor compound enables charge transport. A hole-transporting donor compound transports (predominantly) holes; an electron-transport donor compound transports (predominantly) electrons; a bipolar, in the art somewhat misleadingly also referred to as semi-conducting, donor compound transports holes and electrons. Obviously, if excitons are to be formed by recombination of holes and electrons and the charge-transporting donor compound as such transports either holes only or electrons only, a further compound is required which enables transport of the type of charge not transported by the donor compound which could be, but not necessarily is, the phosphorescent acceptor compound.

Being a donor, the charge-transporting donor polymer is, in the context of the invention, capable of donating a charge and/or an exciton formed on the donor polymer to the phosphorescent acceptor compound and, conversely, the phosphorescent acceptor compound being an acceptor, the phosphorescent acceptor compound is, in the context of the invention, capable of accepting such charge and/or an exciton from the charge-transporting donor polymer. Whether a hole or an electron or an exciton or combination thereof is transferred depends on the specific donor and acceptor compound used. The net effect of the transfer is that energy (in the form of electrical charges) which is injected into the donor compound by means of the bias applied to the electrodes is transferred to the acceptor which acceptor then releases the energy so transferred by phosphorescence.

In accordance with the invention the conjugated chain comprises one or more odd-integer sub-units. An odd-integer sub-unit is a monocyclic or fused polycyclic conjugated multivalent radical. Monocyclic or fused polycyclic conjugated multivalent radicals include multivalent radicals of aromatic compounds.

In order to identify in a particular conjugated chain, the one or more odd-integer sub-units the following method is used:

Identify all monocyclic or fused polycyclic conjugated radicals in the chain. Include unsaturated atoms, exclude saturated atoms. Classify each radical so identified according to its valency either as univalent or multivalent. Of each of the multivalent radicals, establish whether and if so which two unsaturated radical sites of the multivalent radical connect the radical to respective adjacent conjugated sub-units of the conjugated chain. For every such pair of radical sites, find out the shortest uninterrupted path of unsaturated atoms connecting the radical sites and count how many unsaturated atoms there are in the path so obtained, not counting the radical sites. If an odd number is obtained, the sub-unit is odd-integer.

The method is to be applied subject to the following proviso: If the conjugated chain comprises a monocyclic or fused polycyclic conjugated multivalent radical which connects to adjacent conjugated sub-units of the conjugated chain and such sub-unit is or comprises a 5-membered aromatic heterocycle including a —O—, —S— or —N— atom hybridized to have a lone pair which formally contributes two π-electrons to the 5-membered aromatic heterocycle, then such —O—, —S— or —N— atom is, for the purpose of whether such sub-unit is an odd-integer sub-unit, disregarded. More specifically, if the 5-membered aromatic heterocycle is monocyclic, the shortest uninterrupted path of unsaturated atoms shall not include such atom whereas if the 5-membered aromatic heterocycle is part of a fused polycycle the atom is simply treated as a saturated atom.

To illustrate the method, a 2,5-thienylene unit is a monocyclic 5-membered aromatic heterocyclic bivalent radical including an —S— atom hybridized such that it has a lone pair which formally contributes two π-electrons to the 5-membered aromatic heterocycle. Thus for the purpose of determining whether the 2,5-thienylene unit is odd-integer the —S— atom is disregarded leading to a shortest interrupted path of two unsaturated carbon atoms rendering the 2,5-thienylene unit not odd-integer, or more specifically even-integer. Similarly, a 2,5-oxadiazolyl unit and a 2,5-triazolyl unit are even-integer sub-units.

To further illustrate, a 3,6-fluorenylene unit is a bivalent radical which is neither a monocyclic nor a fused polycyclic conjugated sub-unit because the carbon atom in position 9 is saturated and thus not part of the conjugated sub-unit. This makes the 3,6-fluorenylene unit a polycyclic unit which is not fused and which therefore needs to be broken down further into two monocyclic phenylene sub-units. The radical sites of the fluorenylene unit being in the 3 and 6 position respectively, the path length of the shortest path of each phenylene sub-unit is an odd integer. Thus a 3,6-fluorenylene unit is a chain of two odd-integer sub-units connected together.

To still further illustrate, a 3,6-carbazolyl unit (the nitrogen atom is considered to be at position 9) is formally a fused polycyclic bivalent radical. But since it comprises a 5-membered aromatic heterocycle including a —N— atom hybridized to have a lone pair which formally contributes two π-electrons to the 5-membered aromatic heterocycle, the proviso applies, as a result of which the —N— atom is considered to be a saturated atom. Being considered a saturated atom, the 3,6-carbazolyl unit becomes identical to the 3,6-fluorenylene unit and hence is an odd-integer sub-unit.

Obviously, any sub-unit which in accordance with the method above does not qualify as an odd-integer sub-unit is not an odd-integer sub-unit.

At least one, preferably more than one, or more preferably all odd-integer sub-units of a conjugated chain, has or have a shortest uninterrupted path of unsaturated atoms of length 1, 3 or 5 or larger odd integer. A preferred path length is 1. If path length is 1 and derives from a benzene cycle, the sub-unit is also referred to as a “meta” sub-unit.

Each odd-integer sub-unit has adjacent conjugated sub-units connected to it. In general, these adjacent sub-units may or may not be odd-integer sub-units. Typically, in order to achieve high triplet levels, it is preferred to have an upper limit on the number of sub-units which are not odd-integer. Thus, in a particular embodiment of the electroluminescent device in accordance with the invention, the conjugated chain has more than one even-integer conjugated multivalent radical sub-units and the more than one even-integer conjugated multivalent radical sub-units are incorporated in the conjugated chain such that no two even-integer conjugated multivalent radical sub-units are connected to one another.

Similarly, in a preferred embodiment of the electroluminescent device in accordance with the invention, the conjugated chain has a plurality of odd-integer conjugated multivalent radical sub-units and any adjacent conjugated sub-unit which is connected to two odd-integer conjugated multivalent radical sub-units is itself an odd-integer conjugated multivalent radical sub-unit. In this preferred embodiment, apart from any conjugated sub-units which end-cap a conjugated chain, the conjugated chain substantially consists of odd-integer sub-units. Conjugated sub-units which end-cap a conjugated chain by definition cannot be multivalent radicals and therefore not multivalent radicals of the odd-integer variety.

In general, increasing the size (meaning adding more unsaturated atoms to it) of a conjugated system lowers the energy of the excited states (both triplet and singlet). Surprisingly, adding unsaturated atoms in the form of odd-integer sub-units does not raise the energy of the triplet excited state, at least not as much as expected. This capability of the odd-integer sub-unit is adversely affected if the size of the odd-integer sub-unit becomes so large that it by itself, that is without any interaction of the adjacent conjugated units, introduces a low-energy triplet excited state.

Accordingly, in a preferred embodiment of the electroluminescent device in accordance with the invention each of the odd-integer sub-units of the conjugated chain has a size which is sufficiently small to enable the donor polymer to have a lowest-energy triplet level of an energy of about 20,000 cm-1 or higher. Preferably, the energy is about 21,000 cm-1 or higher or more preferably about 22,000 cm-1 or higher. The energy of the triplet level is determined by measuring the phosphorescence emission spectrum, if necessary at reduced temperatures, such as liquid nitrogen temperature, preferably in the solid state but if the quantum yield is too small, in solution. A more than reasonable expectation of success to find such units is to look at the triplet levels of the corresponding conjugated compound of the sub-unit. Another is to select units which have a limited number of unsaturated atoms.

To limit the size of odd-integer sub-units, in another preferred embodiment each of the one or more odd-integer sub-units of the conjugated chain has a total number of unsaturated atoms less than 20. Preferably, the number of atoms is less than 15 or may also be less than 10.

If the conjugated chain comprises adjacent conjugated sub-units which are not odd-integer sub-units then such adjacent units should (also) not be too large.

Accordingly, in a preferred embodiment of the electroluminescent device in accordance with the invention the conjugated chain includes adjacent conjugated sub-units which are not odd-integer sub-units and each of such adjacent conjugated sub-units has a size which is sufficiently small to enable the donor polymer to have a lowest-energy triplet level of an energy of about 20,000 cm-1 or higher. Preferably, the energy is about 21,000 cm-1 or higher or more preferably about 22,000 cm-1 or higher.

Similarly, in another preferred embodiment of the electroluminescent device in accordance with the invention the conjugated chain includes adjacent conjugated sub-units which are not odd-integer sub-units and each of such adjacent conjugated sub-units has a total number of unsaturated atoms less than 20. Preferably, the number of atoms is less than 15 or may also be less than 10.

In a broad sense, the electroluminescent device in accordance with invention has a donor polymer with a conjugated chain comprising one or more odd-integer sub-units.

Particular embodiments of the odd-integer sub-unit include odd-integer multivalent radicals derived from C₄-C₆ monocyclic or C₆-C₂₂ fused polycyclic aromatic compounds which are optionally substituted at one or more positions and in which one or more unsaturated CH units may be replaced with N.

Specific examples of odd-integer sub-units include but are not limited to those having structural formula 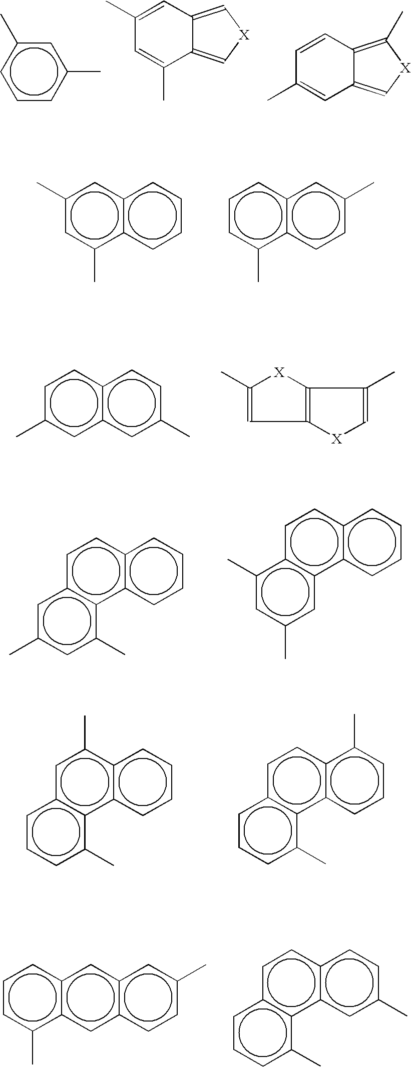
wherein —X— represents —O—, —S—, —NH, —CH₂— or —CH₂CH₂— where each of the hydrogen atoms of —NH, —CH₂— or —CH₂CH₂— is optionally replaced by a non-hydrogen substituent such as the group R⁴ or R⁵ defined below.

In particular, —X— may be —CR′R′— wherein —CR′R′— together represent a cyclic structure in which the carbon atom is a spiro atom. Further, —X— may be —CR′R″CR′R″— wherein —CR′—CR′— together represent a ring system, monocyclic or polycyclic, such as fused polycylic, saturated or aromatic or combination thereof

In particular —X— may be of the formula 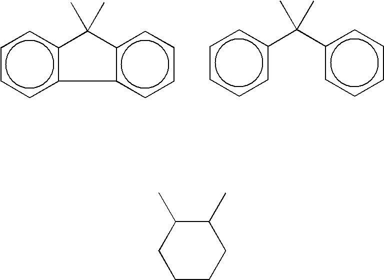
optionally carrying one or more substituents, such as substituents R⁴ or R⁵ defined below. Also preferred is —X— equal to C₁-C₂₀ dialkylmethylene and —NR¹— where R¹ is C₁-C₂₀ alkyl or C₄-C₁₂ aryl such as phenyl.

The conjugated chain may contain adjacent conjugated units which are not odd-integer units. One example is a conjugated sub-unit end-capping a conjugated chain. An end-capping sub-unit is a univalent radical in the sense that it has only one unsaturated radical site which connects the sub-unit to the odd-integer sub-unit adjacent to it. A conjugated side-branch which is end-capped is another variety of a conjugated univalent sub-unit.

Particular embodiments of such univalent radicals include univalent radicals of C₁-C₁₁ polyenes, C₄-C₆ monocyclic aromatic systems or C₈-C₂₂ fused polycyclic aromatic hydrocarbons and combinations thereof.

Examples of univalent conjugated sub-units include vinyl, styryl, phenyl, naphthyl, phenanthryl, phenylphenylene, thienyl, pyrrolyl, oxadiazo-yl, furanyl.

An adjacent conjugated sub-unit may also be an even-integer conjugated multivalent radical sub-unit. Preferred even integers are 0, 2 and 4, most preferably 2. In case of a phenylene, if chain length is 0, the unit is also referred to as “ortho”, if length is 2 as “para”.

Particular embodiments of even-integer sub-unit are even-integer multivalent radicals of C₄-C₆ monocyclic aromatic systems and C₈-C₂₂ fused polycyclic aromatic hydrocarbons.

Examples of even-integer conjugated multivalent radical sub-units include but are not limited to those of the formula: 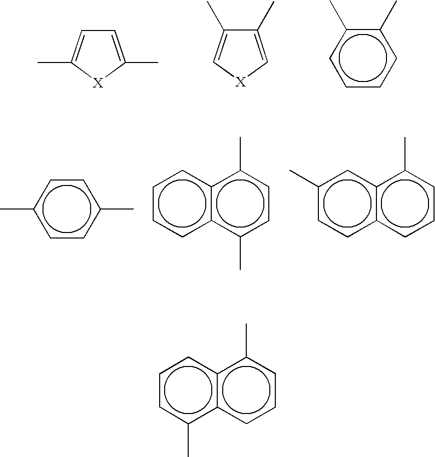
wherein —X— has the meaning as hereinabove. It is to be noted that since the substituent —X— is either a saturated unit or deemed to be saturated unit (see remark above) the 5-membered heterocyclic 2,5- bivalent radical is an even-integer sub-unit.

The adjacent conjugated sub-unit may be a C₂-C₂₀ ene-derived multivalent radical such as a C₄-C₂₀ polyene. As always any conjugated CH unit may be replaced with nitrogen and the ene may or may not be substituted. The adjacent conjugated sub-unit may also be a single-atom conjugated biradical sub-unit, that is a biradical wherein the first and second radical site are one and the same unsaturated atom, examples being —N(R¹)—, —C(R¹)═, —O— and —S—. In the context of the invention, such sub-units are not considered odd-integer. The adjacent conjugated sub-unit may also be any combination of even-integer, univalent, ene-derived or single atom sub-unit.

Any and all conjugated sub-units referred to above, inclusive the particular embodiments and examples, may have one or more unsaturated CH atom replaced with respective unsaturated nitrogen atoms.

Alternatively and/or additionally, the hydrogen atom of each unsaturated CH atom may be replaced with a substituent, the same or different at each replacement.

In particular the number of non-hydrogen atoms of each such substituent is less than 40, preferably less than 20, or more preferable less than 10. More in particular such substituent is in the form of a group R⁴ or a group R⁵ defined below.

Group R⁴ represents C₁-C₂₀ cyclic or acyclic straight or branched alkyl optionally interrupted one or more times with —O—, —OC(═O)—, —C(═O)O—, —S—, secondary nitrogen, tertiary nitrogen, quaternary nitrogen, —CR⁴⁵═CR⁴⁶—, —C≡C—, —C(═O)—, —C(═O)NR⁴⁵—, —NR⁴⁵C(═O)—, —S(═O)—, —S(═O)₂— or a group —X⁶— and/or substituted one or more times with R⁵, R⁷, R⁸, preferably with the proviso that the total number of non-hydrogen atoms is less than 40, better less than 20, or still better less than 12.

Group R⁵ is C₅-C₃₀ aryl wherein, optionally, one or more of the aromatic carbon atoms are replaced with N, O or S, and, optionally, one or more of the aromatic carbon atoms carry a group R⁴, R⁷, R⁸, preferably with the proviso that the total number of non-hydrogen atoms is less 40, better less than 20, or still better less than 12.

Group R⁷ is —CN, —CF₃, —CSN, —NH₂, —NO₂, —NCO, —NCS, —OH, —F, —PO₂, —PH₂, —SH, —Cl, —Br, —I.

Group R⁸ is —C(═O)R⁴⁵, —C(═O)OR⁴⁵, —C(═O)NR⁴⁵R⁴⁶, —NHR⁴⁵, —NR⁴⁵R⁴⁶, —N(⁺)R⁴⁵R⁴⁶R⁴⁷R⁴⁷, —NC(═O)R⁴⁵—, —OR⁴⁵, —OC(═O)R⁴⁵, —SR⁴⁵, —S(═O)R⁴⁵, —S(═O)₂R⁴⁵; wherein R⁴⁵, R⁴⁶, R⁴⁷, the same or different, H, R⁴ or R⁵.

Unit X⁶ is C₄-C₃₀ arylene wherein, optionally, one or more of the aromatic carbon atoms are replaced with N, O or S and, optionally, one or more of the aromatic carbon atoms carry a rest R⁴, R⁷, R⁸.

In a more narrow sense, the invention relates to a specific variety of odd-integer sub-unit, viz. a sub-unit based on a phenylene radical. In such units the term “meta” applies. Specifically, the invention relates to an electroluminescent device comprising a combination of a charge-transporting conjugated donor polymer and a phosphorescent acceptor compound dispersed in the donor polymer, the charge-transporting conjugated donor polymer including a conjugated chain including one or more phenylene-based sub-units, each phenylene-based sub-unit having a first and a second radical site connecting the phenylene-based sub-unit to a respective first and second adjacent conjugated sub-unit of the conjugated chain, the first and the second unsaturated radical site being positioned relative to one another in a meta arrangement.

Chains of odd-integer sub-units may be obtained by simply linking together individual odd-integer sub-units via their respective first and second radical sites. Examples of chains of odd-integer sub-units include those of the formula 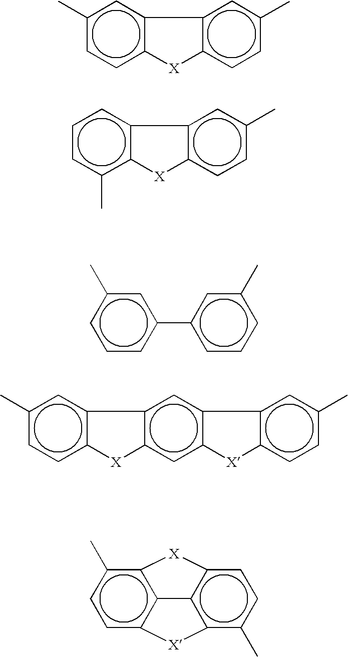
wherein —X— and —X′— are the same or different and have the same meaning as —X— defined above.

It is to be noted that with —X— as defined above the substituent —X— is either a saturated unit or deemed to be saturated unit (see remark above) and accordingly is not part of the conjugated system. Taking this into account, the chains shown are chains of 2 or 3 odd-integer sub-units linked together. The same applies to —X′—.

Various embodiments of donor polymers are suitable. In the context of the invention, the term “polymer” includes “oligomer”, “homopolymer” “copolymer”, “terpolymer”, “quaterpolymer” and higher homologues.

In a first embodiment, the polymer may be a linear chain polymer. A first type of linear chain polymer is the main chain polymer. A main chain polymer has a conjugated chain which is part of the backbone of the polymer. The backbone of the main chain polymer may comprise one conjugated chain but it may also have a plurality of conjugated chains which is the case if the conjugated chains are co-polymerized with saturated chains. The or each conjugated chain of the main chain polymer may have side-branches which may or may not be conjugated. A conjugated side-chain may itself comprise a conjugated chain having one or more odd-integer sub-units. Examples of such conjugated side-branches have been described hereinabove with respect to univalent conjugated sub-units. The linear chain polymer may also be a side-chain polymer having a saturated backbone and a plurality of side chains one or more, but preferably all, of which comprise one or more conjugated chains. In order to increase the density of high-energy triplet states preferably a significant fraction of the side chains comprises a conjugated chain having one or more odd-integer sub-units such as fraction of about 0.2 or more, about 0.5 or more or about 0.7 or more. Most preferably each side chain comprises such a conjugate chain.

The donor polymer may also comprise a branching monomer or more specifically be cross-linked, slightly cross-linked that is to say having cross-linker in an amount of about 5% by weight or less or strongly cross-linked having more than 5% by weight cross-linker. A cross-linked polymer has chains between the cross-links. Each such chain may be a saturated or conjugated chain or combination thereof. In case of a conjugated chain between cross-links the conjugated chain preferably has a size which is sufficiently small so as not adversely affect formation of a high-energy triplet level. This can be done by selecting a conjugate chain which has a limited number of unsaturated atoms such as about 20 or less.

In another aspect, the invention also relates to an electroluminescent device comprising a combination of a charge-transporting conjugated donor polymer having a lowest-energy triplet level with an energy of about 20,000 cm-1 or higher and a lowest-energy single level which is at most 0.5 eV higher in energy than the lowest-energy triplet level, and a phosphorescent acceptor compound having a phosphorescent emission level with an energy of about 20,000 cm-1 or lower.

More particularly, the invention relates to an electroluminescent device comprising a combination of a charge-transporting conjugated donor polymer having a lowest-energy triplet level with an energy of about 21,000 cm-1 or higher and a lowest-energy single level which is at most 0.5 eV higher in energy than the lowest-energy triplet level, and a phosphorescent acceptor compound having a phosphorescent emission level with an energy of about 21,000 cm-1 or lower.

Even more specific, the energy is 22,000 cm-1. The difference in energy is preferably less than about 0.4 eV, more preferably less than about 0.3 eV.

The difference in energy is the difference obtained from of the solid state prompt fluorescence and the phosphorescence emission spectrum. How to obtain an energy from a peak (featureless, shouldered or vibronically progressed peak) in the spectrum is defined hereinabove.

EL devices comprising such combinations have a lowest triplet level which is high enough in energy to avoid back-transfer of excitons from the acceptor to the donor triplet level thus making more excitons available for light emission from the phosphorescent acceptor compound. At the same time the energy difference being less than 0.5 eV makes the singlet level relatively low in energy. A relatively low singlet level is advantageous for efficient injection of holes and/or electrons. The combined effect is a highly efficient electroluminescent device since the efficiency of emission from the phosphorescent acceptor compound is much better than from the donor triplet level. With a triplet energy of 20,000 cm-1 efficient emission of green light and light of lower energy can be obtained whereas with an energy in excess of 21,000 cm-I efficient green and possibly blue emission may be obtained. At 22,000 cm-1 all colors can be emitted with high efficiency. Further, transfer of excitons from the triplet donor level to the emission level of the acceptor is enabled thus improving efficiency of light emission if by recombination of holes and electrons lowest triplet states are formed on the donor compound. Polymer EL devices capable of emitting green light with an efficiency of about 10 Cd/A or even about 15 Cd/A or still better more than about 20 Cd/A can be realized in this manner at low voltages and high brightness such as 100 Cd/m².

Preferably, the energy of the triplet donor level is at least about one kT, more preferably 3kT higher than the acceptor emission level to effectively prevent back-transfer.

It is recalled that the term “phosphorescent” refers to light emission from a state having a lifetime which is substantially longer than the lifetime of a fluorescent state, the lifetime of the latter being typically about 50 ns or less.

In a particular embodiment, the donor polymer and the acceptor compound are integrated to form one integrated donor-acceptor polymer.

The invention is not only useful for donor polymers but may also be of advantage in the case of low molecular weight donor compounds. Accordingly, the invention also relates to an electroluminescent device comprising a combination of a charge-transporting conjugated donor compound and a phosphorescent acceptor compound dispersed in the donor compound, the charge-transporting conjugated donor compound including a structural unit R in accordance with one of the formula 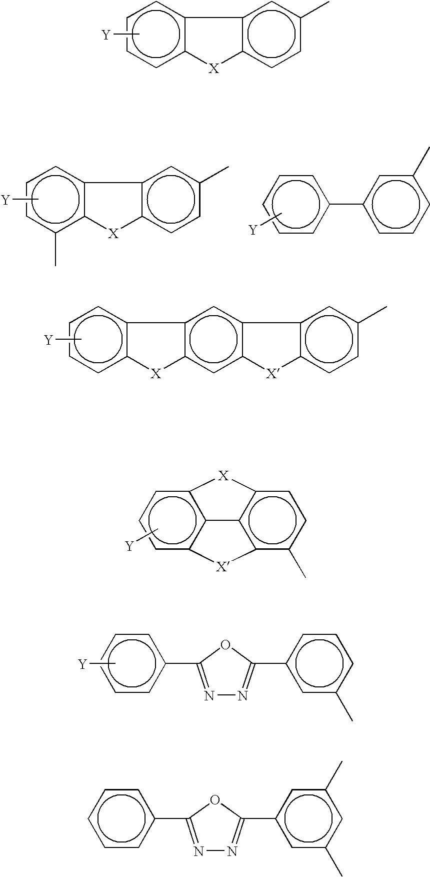
wherein Y is a single bond or a hydrogen, —X— or —X′— is, the same or different, —O—, —S—, —NH—, —CH₂— or —CH₂CH₂— or wherein —X— or —X′— is, the same or different, —CR′R′— wherein —CR′R′— together represent a cyclic structure in which the carbon atom is a spiro atom or wherein —X— or —X′— is, the same or different, —CR′HCR′H— with —CR′—CR′— together representing a ring system, monocyclic or polycyclic, such as fused polycylic, saturated or aromatic or combination thereof, or wherein —X— or —X′— is, the same or different, a structural unit in accordance with one of the formula 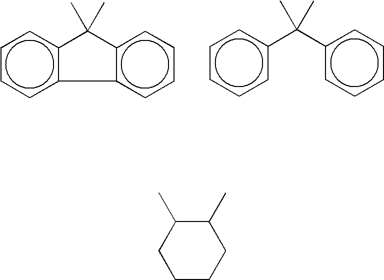
or wherein —X— or —X′— is, the same or different, equal to C¹-C₂₀ dialkylmethylene or —NR¹— with R¹ is C₁-C₂₀ alkyl or C₄-C₁₂ aryl, such as phenyl, and wherein one or more aromatic —CH units may be replaced with respective nitrogen atoms and wherein one or more hydrogen atoms may be replaced with respective non-hydrogen substituents.

For the avoidance of any doubt, particular embodiments of combinations in accordance with this aspect of the invention are obtained by including, mutatis mutandis, features discussed in the context of the other aspects of the invention. In particular, the donor compound may comprise non-hydrogen substituents such as groups R⁴ or R⁵.

The donor compound may be a polymer or a low molecular weight compound. In the context of the invention, small molecular weight means capable of being deposited in the form of a layer by means of a vacuum or organic vapor phase deposition method.

The donor polymer or compound may have units providing functionality other than charge transport and the ability to donate charges and/or excitons to the acceptor compound. Functionality which may be introduced in this manner includes the increased ability to accept electrons or holes from electron or hole-injecting contacts, ability to block or trap holes, electrons and/or excitons, and providing increased hole and/or electron mobility. Providing such further functionality is as such well known in the art and generally is realized by providing appropriate conjugated units. For example electron transport and injection functionality may be provided by including conjugated units having an oxadiazolyl moiety whereas hole-injection and transport capability may be introduced by including amine moieties carrying aromatic substituents such as tetraphenyldiamine moieties. Exciton blocking functionality may be introduced by including units derived from bathocuproin.

The donor compounds and in particular donor polymers used in the combination of the present invention can be synthesized using conventional methods. For details regarding synthesis see the Dutch patent application 1022660 (applicant's reference PHNL030114NLP) of which the present application claims priority and which is, with respect to synthesis, incorporated by reference.

The combination includes a phosphorescent acceptor compound, also referred to as triplet emitter or triplet acceptor. Such compounds are as such well known in the art. Use of such compounds in electroluminescent devices is allegedly of advantage to achieve high efficiencies because of the ability to harvest triplet excitons formed on the donor compound.

Compounds which have a large spin-orbit coupling are good candidates for efficient triplet emitters. Generally, spin-orbit coupling is increased by including in a compound one or more heavy atoms such as Br, Ru, Rh, Pd, In, I, Hf. Ta, Os, Ir, Pt, Au, Hg, Ti, Pb, Zn and Bi or a rare earth metal such as La, Pr, Nd, Eu, Gd, Tb, Dy, Ho, Er and Tm. Whereas, Br and I may be conveniently introduced as covalently bonded substituents, the other elements may be suitably included in the form of a corresponding ion complexed with ligands, where the ligands are organic moieties. Such complexes are well known in the art for their pure light emission and high emission efficiency and include in particular porphyrine and phtalocyanine complexes. Complexes of Pt and Ir are preferred.

Examples of suitable phosphorescent acceptor compounds include but are not limited to those disclosed in U.S. Pat. No. 6,303,238, U.S. Pat. No. 6,310,360, WO00/70655, WO01/41512 and WO 01/39234. Further, Lamanski et al in Inorg. Chem. 40 (2001, page 1704 and Lamanski et al in J. Am. Chem. Soc. 123 (2001), page 4304 disclose the orange-red emitter, iridium(III) bis(2-phenylquinolyl-N,C^{2′}) acetylacetonate, the red emitter Iridium(III) bis(2-(2′-benzothienyl)pyridinato-N,C^{3′}) (acetylacetonate), Iridium(III) bis(2-(2′-thienyl)pyridinato-N,C^{3′}) (acetyl acetonate), Iridium(III) bis(2,4-diphenyloxazolato-1,3-N,C^{2′}) (acetyl acetonate), Iridium(III) bis(3-(2-benzothiazolyl)-7-(diethylamino)-2H-1-benzopyran-2-onato-N′,C⁴) (acetyl acetonate), Iridium(III) bis(2-(2-naphthyl)benzothiazolato-N,C^{2′}) (acetyl acetonate) and Iridium(III) bis(2-phenyl oxazolinato-N,C^{2′}(acetyl acetonate). Commercially available 2,3,7,8,12,13,17,18-Octaethyl-21H,23H-porphyrine platinum (II) may also be used.

Of particular interest are complexes of the formula M³⁺ CL⁻₃ UL wherein M=Eu or Th and CL⁻ is a negatively charged ligand to compensate the ion's charge such as the conjugate base of (2Z)-3-hydroxy-1,3-diphenylprop-2-en-1-one or (4Z)-5-hydroxy-2,2,6,6-tetramethylhept-4-en-3-one or (3Z)-1,1,1-trifluoro-4-hydroxy-4-(2-thienyl)but-3-en-2-on and UL is an uncharged ligand such as 4,7-diphenyl-1,10-phenanthroline, 1,10-phenanthroline or 2,2′-bipyridine or combinations thereof.

The emitters disclosed by Cao et al in J. Mater. Chem 2003, vol 13, page 50.

If to be used in a polymer EL device, it may be prudent to provide one or more ligands with solubilizing groups such as alkyl or alkoxy to improve solubility and hence thin-film-forming ability.

As described above, when a bias is applied to the electrodes of the electroluminescent device of the present invention, the donor picks up energy in the form of charges which energy is then, at least partially, transferred to and accepted by the phosphorescent acceptor compound wherefrom the energy is released by emission of a photon of light. Energy may be provided in the form of holes, electrons and/or excitons (photons). Different routes along which the transfer of energy proceeds can be imagined. Along which route it actually proceeds is not essential to the invention. A typical route along which the picking up and release of energy may occur is injection of holes and electrons onto the donor compound, formation of an exciton on the donor compound by recombination of a hole and electron, transfer of the exciton to the acceptor compound and decay of the exciton residing on the phosphorescent acceptor compound under emission of a photon. Instead of an exciton, a hole or electron may be transferred to the phosphorescent acceptor compound which hole or electron then forms an exciton with an electron or hole respectively already present on or provided later to the phosphorescent acceptor compound. In all routes it is desired that the donor compound serves as the donor of energy and the light-emissive compound as the acceptor of energy.

Efficient transfer of excitons requires the donor excited state level to have an energy higher, preferably slightly higher energy (about 1 to 3 times kT), than the acceptor level. Efficient transfer is achieved if there is spectral overlap of the photo-absorption spectrum of the acceptor and the photo-emission spectrum of the donor. If a hole is to be efficiently transferred, the hole acceptor level is to be higher in energy than the hole donor level (which can be readily checked by measuring the oxidation potential electrochemically). If an electron is to be efficiently transferred the electron acceptor level has to be lower in energy than the electron donor level (which can be readily checked by measuring the reduction potential electrochemically). Efficient transfer of excitons, holes and electrons further requires close proximity, say typically less than about 1 nm, and favorable orientation of donor with respect to acceptor molecule.

In principle any weight ratio of donor and acceptor may be used, for example the acceptor compound may be present in 30% or even more than 50% by weight. When used in relatively small amounts, the acceptor is included in less than 15% by weight or even less than about 10% by weight.

In a particularly favorable embodiment, the donor compound or polymer and the acceptor compound are integrated to form one integrated donor-acceptor compound.

Having such arrangement prevents migration of donor relative to acceptor, thus preventing any aggregation and phase-separation phenomena. From a synthetic point of view, integration of donor and acceptor may be laborious but in principle is straightforward. Both acceptor and donor typically comprise conjugated units. Such units may be linked together using the methods referred to above regarding the synthesis of the donor compound.

A particular embodiment of integrated donor/acceptor compound is one wherein the phosphorescent acceptor is a metal ligand complex where the ligand is a part of the conjugated unit of the donor compound. Particularly suitable ligands in this respect are ligands derived from phenylpyridyl, bipyridyl and phenanthroline. Examples include those of the following formula: 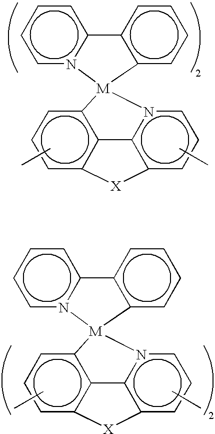
wherein —X— is as defined above and M is a metal-ion as defined above, with M=Ir being preferred. The unit according to the second formula provides cross-links resulting in a particularly stable system. These units may be conveniently combined with the odd-integer and even-integer sub-units as defined above, in particular with units of the formulas given above in view of the structural similarity between the bivalent radical ligand and those sub-units.

The integrated donor-acceptor compound may be a low molecular weight compound for use in a vacuum or organic vapor phase deposition method or a high-molecular-weight compound for use in a wet deposition method. The donor and acceptor units may be separated by saturated atoms or may be linked by conjugated atoms. Donor and/or acceptor units may be pendant groups of a side-chain polymer or may be integrated in the backbone of linear main chain polymer.

The combination of the present invention may include further compounds. Obviously, the combination may include a plurality of phosphorescent acceptor compounds to tune the color of the light emitted, in particular white light. Examples of other further compounds include hole-transport and injecting compounds, electron-transport and injecting compounds, hole, electron and/or exciton blocking or trapping compounds, such compounds being known in the art as such. Singlet or triplet quenching agents, sensitizing agents and agents facilitating inter system crossing may also be added. Additives and agents to facilitate processing such as thin film formation may also be used.

The donor compound, the acceptor compound and combinations thereof have good thin-film forming properties. Vacuum deposition methods require the compounds to be of low molecular weight, whereas wet deposition methods such as spin-coating and printing methods generally require higher molecular weight compounds such as polymers.

When used in EL device, layers comprising the donor or acceptor or the combination thereof are preferably thin, say 1 nm to 500 μM or more particular 10 nm to 10 μm still more particular 20 nm to 1 μm. Preferably the thickness is about 10 nm to 300 nm.

The electroluminescent device in accordance with the invention may, apart from the specific combinations of donor and acceptor compounds in accordance with the invention, be of a conventional construction.

In its simplest form, the electroluminescent device comprises an organic electroluminescent layer (light-emissive layer, LEL) comprising a combination in accordance with the invention dispersed between a hole-injecting and an electron-injecting electrode.

Other more complex device configurations include HIE/HTL/LEL/EIE, HIE/LEL/ETL/EIE, HIE/HTL/LEL/ETL/EIE, HIE/LEL/HBL/EIE, HIE/EBL/LEL/EIE, HIE/HTL/LEL/HBL/EIE, HIE/HTL/EBL/LEL/EIE, HIE/LEL/HBL/ETL/EIE, HIE/HTL/LEL/HBL/ETL/EIE, HIE/HTL/HBL/LEL/ETL/EIE or HIE/HTL/HBL/LEL/EE, HIE/HTL/LEL/XBL/EIE wherein HIE means hole-injection electrode, EIE electron-injecting electrode, HTL hole-transport and/or hole-injection layer, ETL electron-transport and/or injection layer, LEL light-emission layer, HBL hole-blocking layer, EBL electron-blocking layer and XBL exciton blocking layer. Such layers are known in the art as such and may be suitably used in the electroliminescent device in accordance with the invention.

The electroluminescent device may be a light emitting diode comprising a high-work function hole-injecting electrode of organic material such as conductive polymers, or of metal such as Pd, Pt, Au, Ag, Al, and ITO, and a low work function electron-injecting electrode including low work function metal such as Al, Ca, Ba, Sm, Yb, Li, and Mg. Alternatively the electroluminescent device may be a light-emitting electrochemical cell which may be provided with high-work function electron and hole-injecting electrodes.

The electroluminescent device generally comprises a substrate. Suitable substrate materials include glass, ceramics, metals and synthetic resins or combinations of such materials. Typically, since organic electroluminescent devices are sensitive to oxygen and water the substrate serves as a barrier for ingress for water and oxygen. In the case of synthetic resins barrier properties may be improved by including barrier layer(s) of glass, ceramic or metal. Although in particular light emitting chemical cells may have hole-injecting and electron-injecting electrodes which are arranged adjacent one another, typically the organic layer or layers are sandwiched between the electrode layers. In order that light generated in the light emission layer can escape the EL device either the substrate-side (including the substrate) and/or the side facing away from the substrate is made transparent to the light to be emitted. To prevent ingress of oxygen and water the EL device is generally enclosed in an air and waterproof enclosure. Typically the enclosure comprises the substrate and a lid or cover foil glued to the substrate. Epoxy glue may be suitably used provided water getter material is provided to absorb moisture entering the device via the epoxy glue seal.

The EL device may be bottom-emissive, that is emission taking place through the substrate, or top-emissive improving aperture in case of active matrix circuitry being provided on the substrate.

The invention is of particular use in a multi-color or full-color electroluminescent device. The acceptor being typically present in amounts so small that, if the donor and acceptor are provided as part of a single layer, the processing of the different emissive regions is determined by the donor and therefore essentially identical regardless the color emitted. Further, the acceptor compounds being present in small amounts, charge injection and transport processes are typically enabled by the donor compound and therefore essentially color-independent although acceptor compound may take over or significantly influence charge transport.

The EL device may be used as a lighting, signage device or display device such as a segmented or matrix display device. The pixels of the matrix may be passively addressed or actively addressed using active switching elements such as thin-film transistors.

The electroluminescent display devices may be used for hand-held devices such as mobile phones, personal digital assistants and palmtops, notebook computers desktop displays and television applications. Projection systems may also comprise an electroluminescent device.

The combination of donor and acceptor compound of the present invention are not only useful in electroluminescent devices. Examples of other electric and optical applications, in particular electro-optical and electronic applications, are photo-voltaic devices and polymer electronics. Diagnostics of biological samples is another.

In another aspect, the invention relates to a combination of a charge-transporting conjugated donor polymer and a phosphorescent acceptor compound dispersed in the donor polymer, the charge-transporting conjugated donor polymer having a conjugated chain including one or more odd-integer conjugated multivalent radical sub-units, each odd-integer conjugated multivalent radical sub-unit having a first and a second unsaturated radical site connecting the odd-integer conjugated multivalent radical sub-unit to a respective first and second adjacent conjugated sub-unit of the conjugated chain and a shortest uninterrupted path of unsaturated atoms connecting the first and the second radical site, the number of unsaturated atoms of the shortest path being an odd integer.

The invention also relates to a combination of a charge-transporting conjugated donor compound and a phosphorescent acceptor compound dispersed in the donor compound, the charge-transporting conjugated donor compound including a structural unit R in accordance with one of the formula 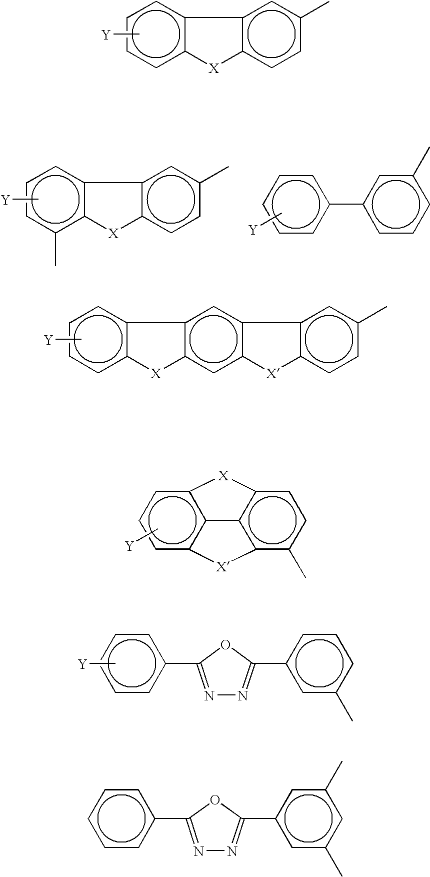
wherein Y is a single bond or a hydrogen, —X— or —X″— is, the same or different, —O—, —S—, —NH—, —CH₂— or —CH₂CH₂— or wherein —X— or —X′— is, the same or different, —CR′R′— wherein —CR′R′— together represent a cyclic structure in which the carbon atom is a spiro atom or wherein —X— or —X′— is, the same or different, —CR′HCR′H— with —CR′—CR′— together representing a ring system, monocyclic or polycyclic, such as fused polycylic, saturated or aromatic or combination thereof, or wherein —X— or —X′— is, the same or different, a structural unit in accordance with one of the formula 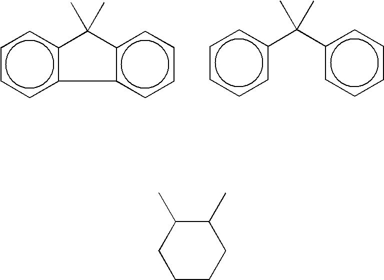
or wherein —X— or —X′— is, the same or different, equal to C₁-C₂₀ dialkylmethylene or —NR¹— with R¹ is C₁-C₂₀ alkyl or C₄-C₁₂ aryl, such as phenyl, and wherein one or more aromatic —CH units may be replaced with respective nitrogen atoms and wherein one or more hydrogen atoms may be replaced with respective non-hydrogen substituents.

For the avoidance of any doubt, features discussed hereinabove in relation to EL devices comprising donor acceptor combinations, in particular the features mentioned in sub-claims of the EL devices may also be used in the combination as such.

The invention further relates to the use of a charge-transporting conjugated donor polymer in a combination of a charge-transporting conjugated donor polymer and a phosphorescent acceptor compound dispersed in the donor polymer, the charge-transporting conjugated donor polymer having a conjugated chain including one or more odd-integer conjugated multivalent radical sub-units, each odd-integer conjugated multivalent radical sub-unit having a first and a second unsaturated radical site connecting the odd-integer conjugated multivalent radical sub-unit to a respective first and second adjacent conjugated sub-unit of the conjugated chain and a shortest uninterrupted chain of unsaturated atoms connecting the first and the second radical site, the number of unsaturated atoms of the shortest chain being an odd integer.

The invention still further relates to the use of a charge-transporting conjugated donor compound in a combination of a charge-transporting conjugated donor compound and a phosphorescent acceptor compound dispersed in the donor compound, the charge-transporting conjugated donor compound including a structural unit R in accordance with one of the formula 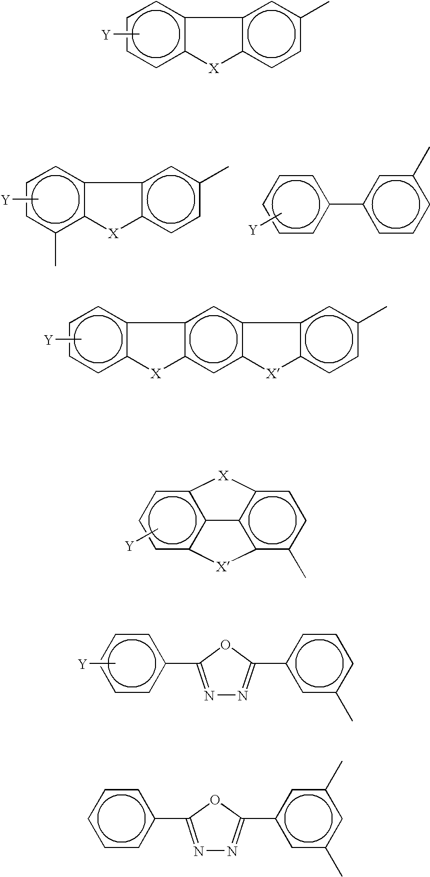
wherein Y is a single bond or a hydrogen, —X— or —X′— is, the same or different, —O—, —S—, —NH—, —CH₂— or —CH₂CH₂— or wherein —X— or —X′— is, the same or different, —CR′R′— wherein —CR′R′— together represent a cyclic structure in which the carbon atom is a spiro atom or wherein —X— or —X′— is, the same or different, —CR′HCR′H— with —CR′—CR′— together representing a ring system, monocyclic or polycyclic, such as fused polycylic, saturated or aromatic or combination thereof, or wherein —X— or —X′— is, the same or different, a structural unit in accordance with one of the formula 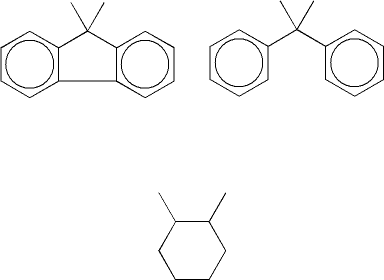
or wherein —X— or —X′— is, the same or different, equal to C₁-C₂₀ dialkylmethylene or —NR¹— with R¹ is C₁-C₂₀ alkyl or C₄-C₁₂ aryl, such as phenyl, and wherein one or more aromatic —CH units may be replaced with respective nitrogen atoms and wherein one or more hydrogen atoms may be replaced with respective non-hydrogen substituents.

These and other aspects of the invention will be apparent from and elucidated with reference to the examples described hereinafter.

### EXAMPLE 1

### 2,5-bis(4-[9,9-bisoctylfluoren-2-yl]phenyl)-1,3,4-oxadiazole (nk475-04)

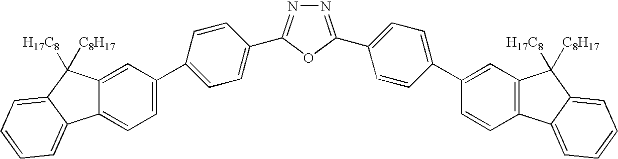 The synthesis of donor compound nk475-04 is described in the Dutch patent application 1022660 (applicant's reference PHNL030114NLP) of which the present application claims priority.

The donor compound nk475-04 has a conjugated chain which extends across the entire molecule. The —C(C₈H₁₇)₂ units are saturated and thus not part of the conjugated chain. The oxygen atom of the oxadiazole cycle formally participates in π-conjugation by means of one of its lone-pairs. However, being an oxygen atom which is part of a 5-membered aromatic heterocycle, for the purpose of determining whether or not the conjugated chain contains an odd-integer sub-unit, the shortest path should not include this oxygen atom rendering the oxadiazole sub-unit an even-integer sub-unit as the shortest path is two unsaturated (nitrogen) atoms long. Identifying the monocyclic and fused polycyclic sub-units in the conjugated chain and labeling them according to one of univalent, even-integer multivalent and odd-integer multivalent results in the following break down: 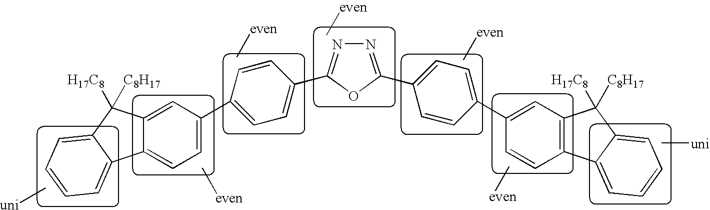
wherein “uni” means a conjugated univalent radical sub-unit, “odd” means an odd-integer conjugated multivalent radical sub-unit and “even” an even-integer conjugated multivalent radical sub-unit. The even-integer sub-units each have a first and a second unsaturated radical site between which an uninterrupted shortest path of unsaturated atoms extends. The number of such atoms in the shortest path of each even-integer sub-unit is 2, an even number. Not having an odd-integer sub-unit implies the conjugated chain is not in accordance with the invention.

The lowest-energy triplet level of nk475-04 is determined by recording the phosphorescent emission spectrum at reduced temperatures. Details of the measurement are provided Dutch patent application 1022660 (applicant's reference PHNL030114NLP). The lowest-energy triplet level has an energy 18,900 cm-1 (2.34 eV, 530 nm). The lowest-energy singlet level, as determined from the prompt fluorescence spectrum, has an energy of 3.30 eV.

### EXAMPLE 2

### 2,5-bis(4-[9-octylcarbazol-3-yl]phenyl)-1,3,4-oxadiazole (nk466-05kk)

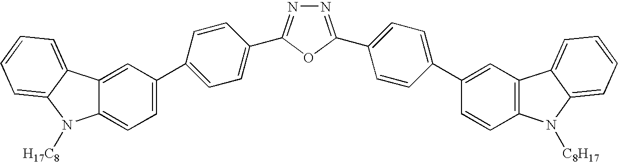

The synthesis of this donor compound nk466-05kk is described in the Dutch patent application 1022660 (applicant's reference PHNL030114NLP) of which the present application claims priority.

The donor compound has a conjugated chain which extends across the entire molecule. The C₈H₁₇ groups are saturated alkyl groups hence not part of it. Like in example 1, the oxadiazole sub-unit is considered to be an even-integer sub-unit. The nitrogen atoms of the carbazole units formally participate in π-conjugation by means of one of their respective lone-pairs. However, since these nitrogen atoms are part of a 5-membered aromatic heterocyclic part of a fused polycycle, for the purpose of determining whether or not the conjugated unit contains an odd-integer sub-unit, it is deemed saturated and hence disregarded.

Taking this into account, identifying the monocyclic and fused polycyclic sub-units in the conjugated chain and labeling them according to one of univalent, even-integer multivalent and odd-integer multivalent results in the following break down:

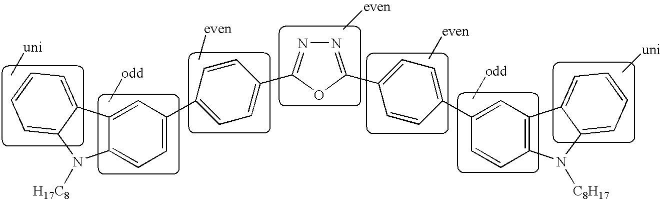

The sub-units labeled “odd” each have an uninterrupted path containing an odd number of unsaturated atoms extending between the first and second unsaturated radical sites. The number of such atoms in the shortest path of each such odd-integer sub-unit is 1, hence the sub-units are odd-integer sub-units.

The 3-substituted carbazolyl sub-unit renders the donor compound if combined with a suitable phosphorescent compound, a donor for use in a combination in accordance with the invention.

The lowest-energy triplet level is measured to be at 19700 cm-1 (2.44 eV) which is substantially higher than the energy of the compound of Example 1. The lowest-energy singlet level, as determined from the prompt fluorescence spectrum, has an energy of 3.24 eV which is lower than the value obtained in Example 1.

Since the conjugated units of the compounds of Examples 1 and 2 differ in the presence of odd-integer sub-units, Examples 1 and 2 demonstrate that introducing odd-integer sub-units in a conjugated chain raises the energy of the triplet level. There is no corresponding change in the singlet level. The singlet has not significantly changed rendering the donor compound equally suitable for charge injection.

### EXAMPLE 3

### 2-phenyl-5-(3,5-bis[9,9-bisoctylfluoren-2-yl]phenyl)-1,3,4-oxadiazole (nk465-05)

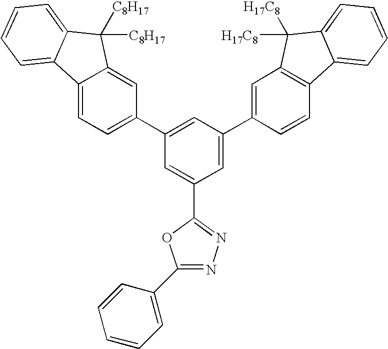

The synthesis of this donor compound is described in the Dutch patent application 1022660 (applicant's reference PHNL030114NLP) of which the present application claims priority.

Having a phenyloxadiazole 3,5 bivalent radical the donor compound nk465-05 is one in accordance with the invention.

The energy of the lowest-energy triplet level is about 20300 cm-1 (2.52 eV).

Having a triplet level in excess of 20,000 cm-1 the donor compound can be combined with a green light-emitting acceptor compound in an EL device, to provide a green light-emitting EL device of high efficiency.

The lowest-energy singlet level has an energy of 3.55 eV.

### EXAMPLE 4

### 2-phenyl-5-(3,5-bis[9-octylcarbazol-3-yl]phenyl)-1,3,4-oxadiazole (nk435-08)

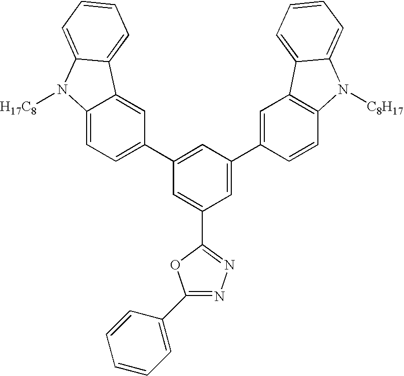

The synthesis of this donor compound is described in the Dutch patent application 1022660 (applicant's reference PHNL030114NLP) of which the present application claims priority.

Having a phenyloxadiazole 3,5 bivalent radical and 3-substituted univalent radical carbazole sub-unit, the donor compound nk435-08 is one in accordance with the invention.

The energy of the lowest-energy triplet level is about 21800 cm-1 (2.70 eV). The lowest-energy singlet level has an energy of 3.55 eV.

The energy of the triplet to an energy (almost to 450 nm) is such that the donor compound may be combined with a blue-emitting phosphorescent acceptor compound without back-transfer taking place opening the possibility to obtain high-efficiency blue-emitting EL devices.

Examples 3 and 4 demonstrate again that substituting even-integer sub-units for odd-integer sub-units raises the energy of the triplet level. This trend is not observed for the lowest-energy singlet levels.

### EXAMPLE 5

Using methods described in the Dutch patent application 1022660 (applicant's reference PHNL030114NLP) of which the present application claims priority, the following compounds were synthesized and the energy of the lowest-energy triplet level measured. 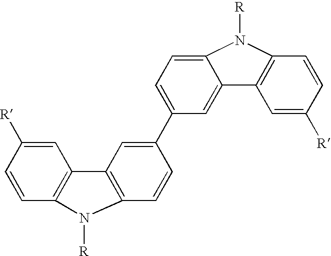
Jjb790-04k: R═C₈H₁₇ and R′═H; triplet energy=22,200 cm-1(451 nm) Jjb796-04k: R=p-methoxyphenyl and R′═H; triplet energy=22,200 cm-1 (451 nm) Jjb82207kk: R═C₈H₁₇ and R′=p-methoxyphenyl; triplet energy=22,000 cm-1 (451 nm) Nk36503k: R═C₈H₁₇ and R′=phenyl; triplet energy=22,100 cm-1 (451 nm) 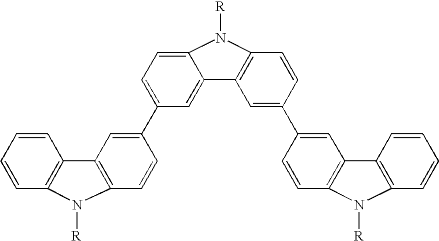
Jjb800-05: R=p-methoxyphenyl; triplet energy=22,000 cm-1 (451 nm) Nk303-05: R═C₈H₁₇; triplet energy=22,000 cm-1 (451 nm)

Example 5 illustrates that by linking together odd-integer sub-units to form a chain of such sub-units the triplet energy remains substantially at the same energy.

### EXAMPLE 6

Using methods analogous to those described in the Dutch patent application 1022660 (applicant's reference PHNL030114NLP) of which the present application claims priority, the following compounds are synthesized: 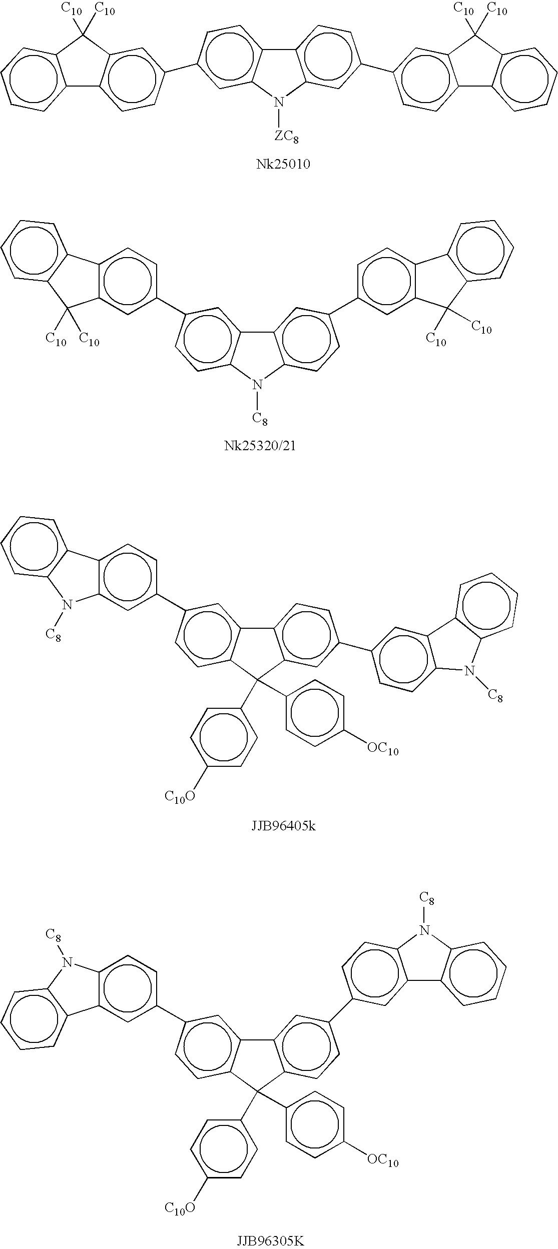
wherein C₈ is octyl and C₁₀3,7-dimethyloctyl.

The lowest-energy triplet level of Nk25010 is 19169 cm-1 (2.38 eV), of Nk25320/21 is 20080 cm-1 (2.49 eV) of JJb96405k is 19320 cm-1 (2.40 eV) and of JJB96305k is 22000 cm-1 (2.73 eV).

The corresponding lowest-energy singlet levels are 3.46, 3.50, 3.25 and 3.33 eV.

The compounds of this Example 6 again clearly illustrate that if in a conjugated chain odd-integer sub-units replace even-integer sub-units the energy of the lowest-energy triplet level is raised. The singlet levels do not change accordingly.

### EXAMPLE 7

Using a method conventional as such, an electroluminescent device is manufactured whose structure is conveniently represented as ITO/PEDOT:PSS/nk380+Irpq/BaAl, wherein “ITO” is an indiumtinoxide hole-injection layer, “PEDOT:PSS” is a hole-transport layer of poly-styrenesulphonic acid (PSS) doped poly-ethylenedioxythiophene (PEDOT) as available from Bayer AG or HC Starck, “nk380+Irpq” is a light-emissive layer comprising a combination of the charge-transporting conjugated donor compound nk380 and the orange light-emitting phosphorescent acceptor compound Irpq, and “BaAl” is an electron-injecting electrode layer of a Ba layer and an Al layer. The phosphorescent acceptor compound is present in 8% by weight.

The charge-transporting conjugated donor compound nk380 is a polymer of the formula TP 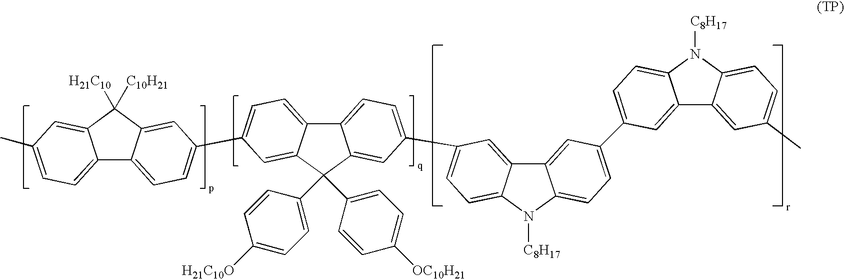
wherein the indices p, q and r indicate the percentage of the structural unit present in the polymer, specifically p=0, q=50 and r=50, C₈ is n-octyl and C₁₀ is 3,7-dimethyloctyl. The synthesis of this donor compound nk380 is described in the Dutch patent application 1022660 (applicant's reference PHNL030114NLP) of which the present application claims priority.

Identifying any odd-integer sub-units in the conjugated chain of the polymer nk380 results in the following:

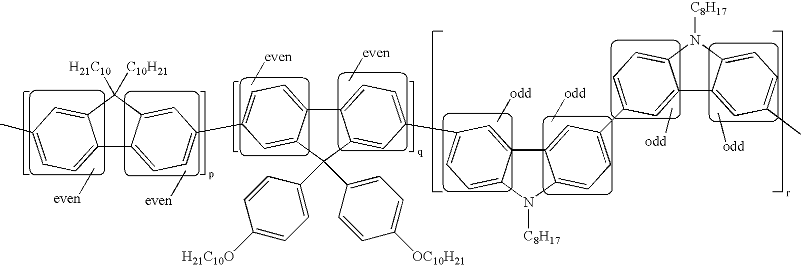

The polymer comprises odd-integer sub-units and is therefore suitable for use in electroluminescent device in accordance with the invention.

The lowest-energy triplet level of nk380 is about 2.15 eV. This is the value obtained from the solid state phosphorescence emission spectrum recorded of the light-emissive layer of the EL device. The corresponding lowest-energy singlet level obtained from the prompt fluorescence spectrum is 2.95 eV.

The orange light-emitting phosphorescent acceptor compound Irpq is short for iridium(III) bis(2-phenylquinolyl-N,C^{2′}) acetylacetonate, is disclosed in Lamansky et al in, J. Am. Chem. Soc. 123 (2001) 4304.

When a bias is applied to the electrode layers of the EL device a current is passed. Since the phosphorescent acceptor compound is present in too small an amount to by itself facilitate all the charge transport and there is no other further compound than the donor compound present in the light-emitting layer, the conclusion must be that the donor compound is charge transporting. More particular, since the EL device emits light for which transport of holes and electrons is necessary the donor polymer is bipolar. At a bias of about 5 V or higher the EL device emits light. The color of the light emitted is orange which is the emission color of the phosphorescent acceptor compound. Emission from the donor compound is substantially absent. Since the donor compound facilitates charge transport, light emission from the acceptor implies that, in operation, energy is being transferred from the donor compound to the acceptor compound.

The efficiency of the EL device depends on the magnitude of the bias applied. At 7 V, the efficiency is about 6 cd/A, at 15 V it is about 12 cd/A. This efficiency is high which is considered to be commensurate with the fact that the triplet of the donor is above the emission level of the acceptor. Accordingly, the combination of the present example and the EL device comprising this combination is in accordance with the invention.

### EXAMPLE 8

An EL device is manufactured which is identical to that of Example 7 except that the orange-emitting phosphorescent acceptor compound is replaced by a green-emitting phosphorescent acceptor compound Ir(ppy)₃. Ir(Ppy)₃ is a well known emitter; it is short for fac tris(2-phenylpyridine) iridium. Ir(ppy)₃ is available from American Dye Source Inc. Solubility of Ir(ppy)₃ is limited. Solubility may be increased by attaching solubilizing substituents, such as alkyl or alkoxy groups, to the ligands of the complex.

When applying a bias to the electrodes of the EL device so obtained, current is passed and light is emitted. The emission spectrum shows predominant light emission from the acceptor and a slight blue emission originating from the host polymer indicating that transfer of energy takes place from the donor to the acceptor. However, the EL efficiency of the EL device is about 2.5 cd/A which is much less than the efficiency of the device of Example 7. The significantly lower efficiency is considered to be a consequence of the fact that the energy of the triplet level of the donor (which is 2.15 eV) is significantly lower than the energy of the emission level of the acceptor (peak value about 550 nm which corresponds to 2.25 eV). As a result, transfer of triplet excitons from donor to acceptor is not possible and back-transfer of excitons from the emission level of the acceptor to the triplet level of the donor is readily possible. This back-transfer is irreversible. Since the emission from the triplet donor level is a forbidden transition, the efficiency of light emission from this level is very low. Accordingly, the efficiency of the EL device is very low.

### EXAMPLE 9

An EL device is manufactured which is identical to that of Example 8 except that the donor polymer is replaced with the polymer nk477.

The polymer nk477 has the structural formula TP3 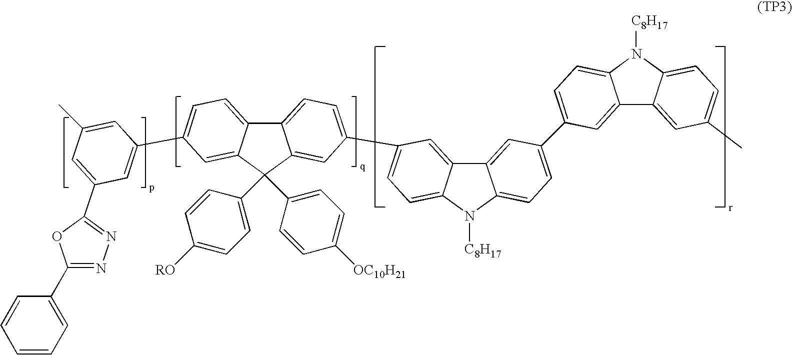
wherein R═OC₁₀H₂₁, OC₁₀H₂₁ is 3,7-dimethyloctyloxy and C₈H₁₇ is n-octyl and p=50, q=0 and r=50.

The synthesis of this donor compound nk477 is described in the Dutch patent application 1022660 (applicant's reference PHNL030114NLP) of which the present application claims priority.

The lowest-energy triplet level of this polymer is about 2.56 eV (20,600 cm-1, 500 nm). This is the value obtained from a solid-state measurement of the light-emitting layer of the EL device. The corresponding lowest-energy singlet level obtained from the prompt florescence spectrum is about 2.84 eV providing a singlet triplet energy difference of only 0.28 eV.

The conjugated main chain of the repeating unit of the polymer nk477 consists of odd-integer sub-units only. The oxadiazole is part of a conjugated side-chain.

Applying a bias to the electrodes of the EL device results in green light emission having a spectrum identical to that of the Ir(ppy)₃ acceptor compound. No emission of blue light of the host polymer nk477 is observed. The light emitted by the acceptor is a saturated green having chromaticity coordinates (0.343; 0.634). Apparently, transfer of energy from donor to acceptor takes place so quickly that luminescence of the host polymer is completely quenched.

The efficiency of the EL device is about 15 cd/A at a bias of about 7 to 9 V. This efficiency is much higher than obtained for the EL device of Example 8. This difference in efficiency is commensurate with the fact that—in contrast to Example 8—the donor triplet level is higher in energy than the emission level of the acceptor compound (which is about 550 nm). This would enable transfer of triplet excitons from donor to acceptor and prevents back-transfer of excitons from acceptor to donor. Accordingly, the combination of donor and acceptor of this example and the EL device comprising this combination is in accordance with the invention.

### EXAMPLE 10

A polymer is obtained by polymerizing 50 mol % bis[3-{4,4,5,5-tetramethyl-1,3,2-dioxaborolyl}-9-(3,7-dimethyloctyl)carbazol-6-yl] 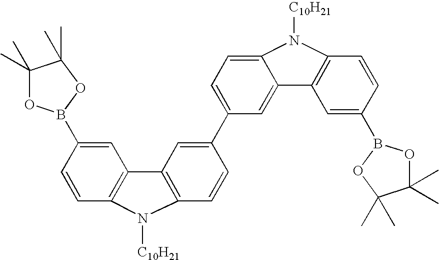
45.5 mol % 2-phenyl-5-(3,5-dibromophenyl)-1,3,4-oxadiazole 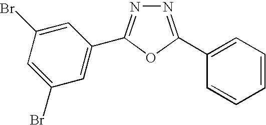
and 3 mol % 1,3,5-tribromobenzene 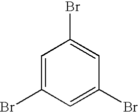
the polymer being referred to as jjb994.

The synthesis of the monomers and the method of polymerization is described in the Dutch patent application 1022660 (applicant's reference PHNL030114NLP) of which the present application claims priority.

In the polymer, the bromo compounds and boron compounds are incorporated in a strictly alternating manner whereas in principle the bromo compounds between each other are randomly incorporated. Since 1,3,5-tribromobenzene has three reactive groups it is a cross-linker and the polymer jjb994 is cross-linked, more specifically slightly cross-linked as it contains less than 5 mol % cross-linker.

The polymer jjb994 has a 100% odd-integer sub-units in the conjugated main chain and has phenyl-oxadiazole units as side-chains. The lowest-energy triplet level of this polymer is about 2.56 eV. This is the value obtained from a solid-state measurement of the light-emissive layer of the EL device. The corresponding lowest-energy singlet level obtained from the prompt florescence spectrum is about 2.84 eV providing a singlet triplet energy difference of only 0.28 eV.

An EL device is manufactured which is identical to that of the previous example except that the donor compound is now the polymer jjb994.

When applying a bias to the EL device, green light emission characteristic of the Ir(ppy)3 acceptor is observed indicating that energy transfer between donor and acceptor has taken place.

The efficiency of the EL device is measured to be about 20 to 24 cd/A. This efficiency is very high and moreover this efficiency is obtained irrespective of the current density within the EL device; efficiency is at least substantially constant in the range of 0 to 500 A/m². Remarkably, the high efficiency is obtained with a two-layer (PEDOT:PSS and light-emissive layer) device.

### EXAMPLE 11

Example 8 is repeated with the difference that as donor compound the polymer jjb857 is used.

Polymer jjb857 is according to structural formula TP3 wherein p=20, q=50 and r=30. The synthesis of the polymer is described in the Dutch patent application 1022660 (applicant's reference PHNL030114NLP) of which the present application claims priority.

The conjugated main chain of the polymer jjb857 has several odd-integer sub-units.

The lowest-energy triplet level of this polymer is about 2.29 eV. This is the value obtained from a solid-state measurement of the light-emissive layer of the EL device. The corresponding lowest-energy singlet level obtained from the prompt florescence spectrum is about 2.79 eV providing a singlet triplet energy difference of only 0.50 eV.

When the EL device is biased green light emission characteristic of the Ir(ppy)₃ is observed with an efficiency of about 7.5 cd/A.

### EXAMPLE 12

On an ITO-covered glass substrate, a layer stack HTL/LEL/HBL/ETL/EIE is deposited by means of vacuum deposition having the following composition:

30.1 nm α-NPD/30 nm (91.7% wt Jjb796-04k, 8.3% wt Ir(ppy)₃)/10 nm bathocuproin/40 nm Alq₃/1.5 nm Li-benzoate/70 nm Al wherein α-NPD is N,N′-di(naphtalen-1-yl)-N,N′-diphenyl-benzidine and bathocuproin is 2,9-dimethyl-4,7-diphenyl-1,10-phenantroline. Alq₃ is aluminum trisoxine. The carbazole donor compound Jjb796-04k is evaporated at 240° C.

The device emits green light characteristic of the phosphorescent acceptor compound Ir(ppy)₃). The external efficiency of the device is about 30 to 35 cd/A. A device having 15 to 25 cd/A external efficiency is obtained if the dimer carbazole Jjb796-04k is replaced with the carbazole trimer Jjb800-05.

Although not necessarily wishing to be bound by any theory, it is believed that such efficiencies can only be obtained if triplet excitons on the carbazole donor compound are efficiently transferred to the phosphorescent acceptor compound and/or triplet excitons on the triplet emitter are effectively prevented from being transferred to the carbazole donor compound. Such efficient transfer and/or effective prevention of back-transfer requires the lowest-energy triplet level of the carbazole donor compound to be located above the emitter level of the phosphorescent acceptor compound. The triplet level of the carbazole Jjb796-04k is about 22,200 cm-1 and of the donor compound Jjb800-05 22,000 cm-1. The emitter level of Ir(ppy)3 is about 18,000 cm-1.

1. An electroluminescent device comprising a combination of a charge-transporting conjugated donor polymer and a phosphorescent acceptor compound dispersed in the donor polymer, the charge-transporting conjugated donor polymer having a conjugated chain including one or more odd-integer conjugated multivalent radical sub-units, each odd-integer conjugated multivalent radical sub-unit having a first and a second unsaturated radical site connecting the odd-integer conjugated multivalent radical sub-unit to a respective first and second adjacent conjugated sub-unit of the conjugated chain and a shortest uninterrupted path of unsaturated atoms connecting the first and the second radical site, the number of unsaturated atoms of the shortest path being an odd integer.

2. An electroluminescent device as claimed in claim 1, wherein the number of unsaturated atoms of the shortest uninterrupted path of at least one of the odd-integer conjugated multivalent radical sub-units is 1.

3. An electroluminescent device as claimed in claim 1 wherein the conjugated chain has more than one even-integer conjugated multivalent radical sub-units and the more than one even-integer conjugated multivalent radical sub-units are incorporated in the conjugated chain such that no two even-integer conjugated multivalent radical sub-units are connected to one another.

4. An electroluminescent device as claimed in claim 1 wherein the conjugated chain has a plurality of odd-integer conjugated multivalent radical sub-units and any adjacent conjugated sub-unit which is connected to two odd-integer conjugated multivalent radical sub-units is itself an odd-integer conjugated multivalent radical sub-unit.

5. An electroluminescent device as claimed in claim 1 wherein each of the odd-integer sub-units of the conjugated chain has a size which is sufficiently small to enable the donor polymer to have a lowest-energy triplet level of an energy of about 20,000 cm-1 or higher.

6. An electroluminescent device as claimed in claim 1 wherein each of the one or more odd-integer sub-units of the conjugated chain has a total number of unsaturated atoms less than 20.

7. An electroluminescent device as claimed in claim 1 wherein the conjugated chain includes adjacent conjugated sub-units which are not odd-integer sub-units and each of such adjacent conjugated sub-units has a size which is sufficiently small to enable the donor polymer to have a lowest-energy triplet level of an energy of about 20,000 cm-1 or higher.

8. An electroluminescent device as claimed in claim 1 wherein the conjugated chain includes adjacent conjugated sub-units which are not odd-integer sub-units and each of such adjacent conjugated sub-units has a total number of unsaturated atoms less than 20.

9. An electroluminescent device comprising a combination of a charge-transporting conjugated donor polymer and a phosphorescent acceptor compound dispersed in the donor polymer, the charge-transporting conjugated donor polymer including a conjugated chain including one or more phenylene-based sub-units, each phenylene-based sub-unit having a first and a second radical site connecting the phenylene-based sub-unit to a respective first and second adjacent conjugated sub-unit of the conjugated chain, the first and the second unsaturated radical site being positioned relative to one another in a meta arrangement.

10. An electroluminescent device comprising a combination of a charge-transporting conjugated donor polymer having a lowest-energy triplet level with an energy of about 20,000 cm-1 or higher and a lowest-energy singlet level which is at most 0.5 eV higher in energy than the lowest-energy triplet level, and a phosphorescent acceptor compound having a phosphorescent emission level with an energy of about 20,000 cm-1 or lower.

11. An electroluminescent device comprising a combination of a charge-transporting conjugated donor polymer having a lowest-energy triplet level with an energy of about 21,000 cm-1 or higher and a lowest-energy singlet level which is at most 0.5 eV higher in energy than the lowest-energy triplet level, and a phosphorescent acceptor compound having a phosphorescent emission level with an energy of about 21,000 cm-1 or lower.

12. An electroluminescent device as claimed in claim 1, wherein the donor polymer and the acceptor compound are integrated to form one integrated donor-acceptor polymer.

13. An electroluminescent device comprising a combination of a charge-transporting conjugated donor compound and a phosphorescent acceptor compound dispersed in the donor compound, the charge-transporting conjugated donor compound including a structural unit R in accordance with one of the formula 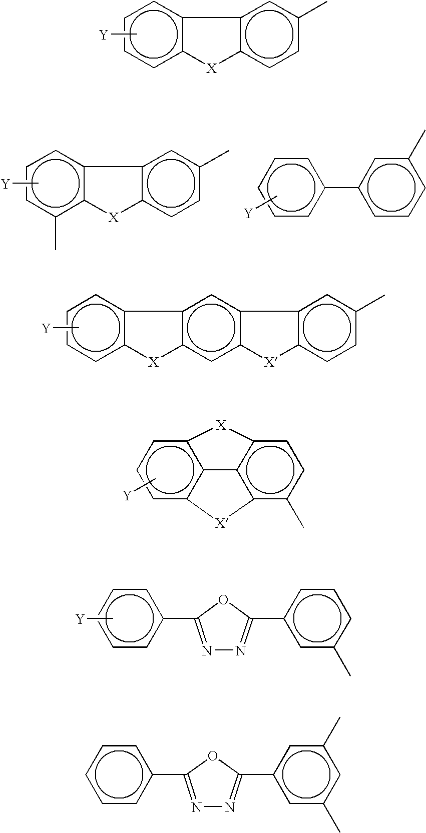
wherein Y is a single bond or a hydrogen, —X— or —X′— is, the same or different, —O—, —S—, —NH—, —CH₂— or —CH₂CH₂— or wherein —X— or —X′— is, the same or different, —CR′R′— wherein —CR′R′— together represent a cyclic structure in which the carbon atom is a spiro atom or wherein —X— or —X′— is, the same or different, —CR′HCR′H— with —CR′—CR′— together representing a ring system, monocyclic or polycyclic, such as fused polycylic, saturated or aromatic or combination thereof, or wherein —X— or —X′— is, the same or different, a structural unit in accordance with one of the formula 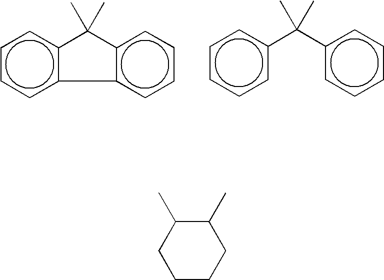
or wherein —X— or —X′— is, the same or different, equal to C₁-C₂₀ dialkylmethylene or —NR¹— with R¹ is C₁-C₂₀ alkyl or C₄-C₁₂ aryl, such as phenyl, and wherein one or more aromatic —CH units may be replaced with respective nitrogen atoms and wherein one or more hydrogen atoms may be replaced with respective non-hydrogen substituents.

14. An electroluminescent device as claimed in claim 13, wherein the donor compound is a donor polymer having a conjugated chain comprising the structural unit R.

15. An electroluminescent device as claimed in claim 13, wherein the donor compound and the acceptor compound are integrated to form one integrated donor-acceptor compound.

16. A combination of a charge-transporting conjugated donor polymer and a phosphorescent acceptor compound dispersed in the donor polymer, the charge-transporting conjugated donor polymer having a conjugated chain including one or more odd-integer conjugated multivalent radical sub-units, each odd-integer conjugated multivalent radical sub-unit having a first and a second unsaturated radical site connecting the odd-integer conjugated multivalent radical sub-unit to a respective first and second adjacent conjugated sub-unit of the conjugated chain and a shortest uninterrupted path of unsaturated atoms connecting the first and the second radical site, the number of unsaturated atoms of the shortest path being an odd integer.

17. A combination of a charge-transporting conjugated donor compound and a phosphorescent acceptor compound dispersed in the donor compound, the charge-transporting conjugated donor compound including a structural unit R in accordance with one of the formula 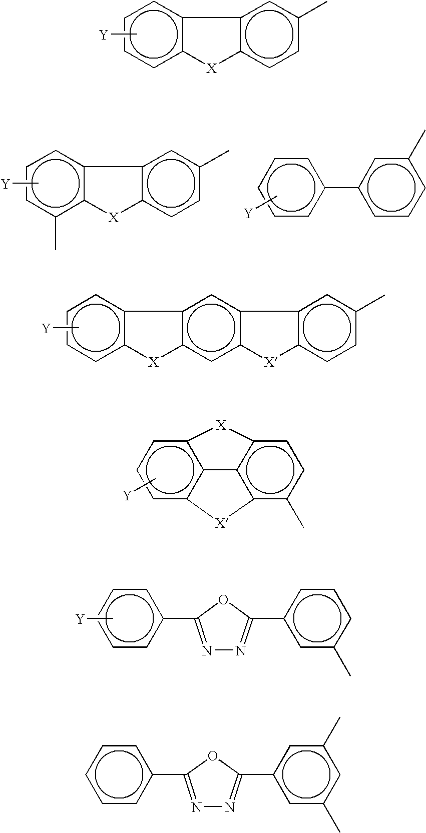
wherein Y is a single bond or a hydrogen, —X— or —X′— is, the same or different, —O—, —S—, —NH—, —CH₂— or —CH₂CH₂— or wherein —X— or —X′— is, the same or different, —CR′R′— wherein —CR′R′— together represent a cyclic structure in which the carbon atom is a spiro atom or wherein —X— or —X′— is, the same or different, —CR′HCR′H— with —CR′—CR′— together representing a ring system, monocyclic or polycyclic, such as fused polycylic, saturated or aromatic or combination thereof, or wherein —X— or —X′— is, the same or different, a structural unit in accordance with one of the formula 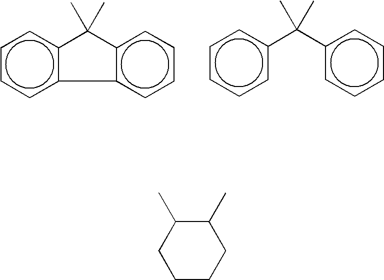
or wherein —X— or —X′— is, the same or different, equal to C₁-C₂₀ dialkylmethylene or —NR¹— with R¹ is C₁-C₂₀ alkyl or C₄-C₁₂ aryl, such as phenyl, and wherein one or more aromatic —CH units may be replaced with respective nitrogen atoms and wherein one or more hydrogen atoms may be replaced with respective non-hydrogen substituents.

18. Use of a charge-transporting conjugated donor polymer in a combination of a charge-transporting conjugated donor polymer and a phosphorescent acceptor compound dispersed in the donor polymer, the charge-transporting conjugated donor polymer having a conjugated chain including one or more odd-integer conjugated multivalent radical sub-units, each odd-integer conjugated multivalent radical sub-unit having a first and a second unsaturated radical site connecting the odd-integer conjugated multivalent radical sub-unit to a respective first and second adjacent conjugated sub-unit of the conjugated chain and a shortest uninterrupted chain of unsaturated atoms connecting the first and the second radical site, the number of unsaturated atoms of the shortest chain being an odd integer.

19. Use of a charge-transporting conjugated donor compound in a combination of a charge-transporting conjugated donor compound and a phosphorescent acceptor compound dispersed in the donor compound, the charge-transporting conjugated donor compound including a structural unit R in accordance with one of the formula 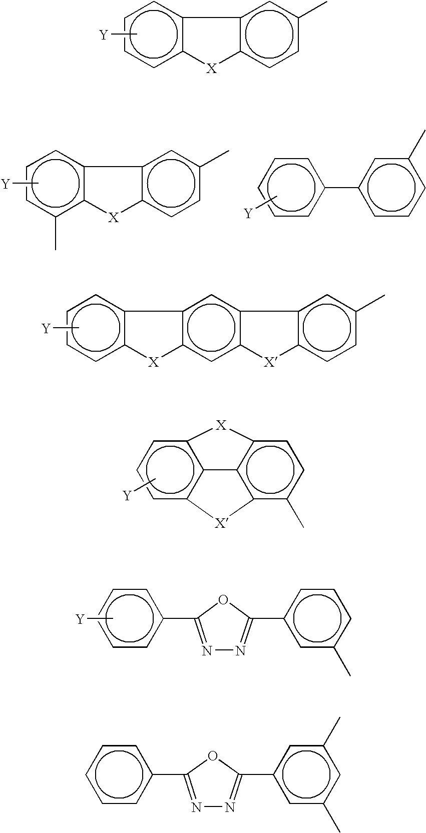
wherein Y is a single bond or a hydrogen, —X— or —X′— is, the same or different, —O—, —S—, —NH—, —CH₂— or —CH₂CH₂— or wherein —X— or —X′— is, the same or different, —CR′R′— wherein —CR′R′— together represent a cyclic structure in which the carbon atom is a spiro atom or wherein —X— or —X′— is, the same or different, —CR′HCR′H— with —CR′—CR′— together representing a ring system, monocyclic or polycyclic, such as fused polycylic, saturated or aromatic or combination thereof, or wherein —X— or —X′— is, the same or different, a structural unit in accordance with one of the formula 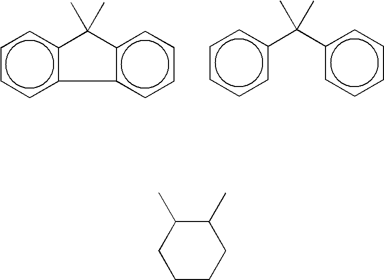
or wherein —X— or —X′— is, the same or different, equal to C₁-C₂₀ dialkylmethylene or —NR¹— with R¹ is C₁-C₂₀ alkyl or C₄-C₁₂ aryl, such as phenyl, and wherein one or more aromatic —CH units may be replaced with respective nitrogen atoms and wherein one or more hydrogen atoms may be replaced with respective non-hydrogen substituents.
